(19) United States
(12) Patent Application Publication
(10) Pub. No.: US 2010/0193001 A1
(43) Pub. Date: Aug. 5, 2010

(54) THERMOELECTRIC CONVERSION MODULE, AND HEAT EXCHANGER, THERMOELECTRIC TEMPERATURE CONTROL DEVICE AND THERMOELECTRIC GENERATOR EMPLOYING THE SAME

(75) Inventors: Shinsuke Hirono, Kanagawa-ken (JP); Masami Okamura, Kanagawa-ken (JP); Fumiyuki Kawashima, Chiba-ken (JP)

Correspondence Address: FOLEY AND LARDNER LLP;SUITE 500, 3000 K STREET NW, WASHINGTON, DC, 20007, US

(73) Assignees: Kabushiki Kaisha Toshiba; Toshiba Materials Co., Ltd.

(21) Appl. No.: 12/666,958

(22) PCT Filed: Jun. 23, 2008
(86) PCT No.: PCT/JP2008/001610

§ 371 Date: Dec. 28, 2009

(30) Foreign Application Priority Data
Jul. 9, 2007 (JP) 2007-179768

(51) Int. Cl. H01L 35/30; H01L 35/20

(52) U.S. Cl. 136/205; 136/240; 136/239

(57) ABSTRACT

A thermoelectric conversion module (10) comprises a first electrode member (13) arranged on a low temperature side, a second electrode member (14) arranged on a high temperature side, and p-type and n-type thermoelectric elements (11 and 12) arranged between and connected electrically with both the first and second electrode members (13 and 14). The thermoelectric elements (11 and 12) are composed of a thermoelectric material (half-Heusler material) containing an intermetallic compound having an MgAgAs crystal structure as a main phase and have a fracture toughness value K_{1C} of not less than 1.3 MPa·m^{1/2} and less than 10 MPa·m^{1/2}.

### TECHNICAL FIELD

The present invention relates to a thermoelectric conversion module using a thermoelectric material containing an intermetallic compound having an MgAgAs type crystal structure as a main phase, and a heat exchanger, a thermoelectric temperature control device and a thermoelectric generator employing the same.

### BACKGROUND ART

The thermoelectric element is expected as a device for recovering the energy which has been discarded as exhaust heat into the atmosphere. The thermoelectric element is used as a thermoelectric conversion module having p-type thermoelectric elements (p-type thermoelectric semiconductors) and n-type thermoelectric elements (n-type thermoelectric semiconductors) which are alternately connected in series. To apply the thermoelectric conversion module to a thermoelectric generator for generating electric power from waste heat or the like, a thermoelectric element usable in a high temperature environment of 300° C. or higher is demanded.

As such a thermoelectric element, there is a known thermoelectric material (hereinafter called a half-Heusler material) having an intermetallic compound which has an MgAgAs type crystal structure as a main phase (see Patent References 1 and 2). It is reported that the half-Heusler material exhibits a semiconducting property and partially exhibits a high Seebeck effect under room temperature. The half-Heusler material has a usable high temperature and is expected to improve the thermoelectric conversion efficiency, so that it is expected as a thermoelectric element material useful for a thermoelectric generator using a high temperature heat source. To use the half-Heusler material for the thermoelectric generator, it is important to realize a highly reliable module structure durable against a high temperature.

For example, when the thermoelectric conversion module is used at a high temperature, a large thermal stress is produced in the bonded portions between the thermoelectric elements and the electrode members due to a thermal expansion coefficient difference between the p-type thermoelectric elements and the n-type thermoelectric elements and a thermal expansion coefficient difference between the thermoelectric elements and the electrode members. In addition, a temperature difference and a heat cycle are often produced between top and bottom surfaces of the thermoelectric conversion module in actual use. Therefore, the thermoelectric conversion module having many bonded portions of different materials has a problem that it is hard to secure reliability in a high temperature environment of, for example, 300° C. or higher for a long period.

Fracture of the thermoelectric module mostly occurs near the bonded interfaces between the thermoelectric elements and the electrode members where a thermal stress is concentrated, and when bonding is performed properly, an initial crack is generated not in the bonded portion itself but in the thermoelectric element near the bonded portion. The internal resistance of the thermoelectric module is increased because of the initial crack to finally break the thermoelectric module. Specially, since the half-Heusler material has the intermetallic compound as the main phase, it has a problem that it is readily cracked. In case where the high temperature side becomes 300° C. or higher, the generated thermal stress is very large, so that it is significant to improve the mechanical properties of the thermoelectric element where the initial crack occurs, and especially the mechanical properties of the thermoelectric element composed of the half-Heusler material in order to satisfy a heat cycle resistance of the thermoelectric module at practical level.

Patent Reference 1: JP-A 2004-356607 (KOKAI)

Patent Reference 2: JP-A 2005-116746 (KOKAI)

### DISCLOSURE OF INVENTION

According to an aspect of the present invention, there are provided a thermoelectric conversion module whose practical use and reliability are improved by improving mechanical properties of a thermoelectric element composed of a half-Heusler material, and a heat exchanger, a thermoelectric temperature control device and a thermoelectric generator employing the same.

A thermoelectric conversion module according to the invention comprises a first electrode member arranged on a low temperature side, a second electrode member arranged on a high temperature side in opposite to the first electrode member, and thermoelectric elements arranged between and connected electrically with both the first and second electrode members, wherein the thermoelectric elements are composed of a thermoelectric material containing an intermetallic compound having an MgAgAs type crystal structure as a main phase and have a fracture toughness value K_{1C} of not less than 1.3 MPa·m^{1/2} and less than 10 MPa·m^{1/2}.

A heat exchanger according to the invention comprises a heating surface, a cooling surface, and the thermoelectric conversion module according to the invention disposed between the heating surface and the cooling surface. In addition, a thermoelectric temperature control device according to the invention comprises the thermoelectric conversion module according to the invention, wherein a cooling or heating function of the thermoelectric conversion module is used to adjust a temperature. A thermoelectric generator according to the invention comprises the heat exchanger according to the invention and a heat supply unit for supplying heat to the heat exchanger, wherein electric power is generated by converting the heat supplied by the heat supply unit into the electric power by the thermoelectric conversion module in the heat exchanger.

### BRIEF DESCRIPTION OF THE DRAWINGS

FIG. 1 is a sectional view showing a structure of a thermoelectric conversion module according to an embodiment of the present invention.

FIG. 2 is a diagram showing a crystal structure of an MgAgAs type intermetallic compound.

FIG. 3 is a sectional view showing a modified example of the thermoelectric conversion module shown in FIG. 1.

FIG. 4 is a sectional view showing a structure of a heat exchanger according to an embodiment of the present invention.

FIG. 5 is a diagram showing a structure of a waste incineration system applying the thermoelectric generator according to an embodiment of the present invention.

FIG. 6 is a diagram showing the measured results of fracture toughness values of n-type thermoelectric elements of Example 1 and Comparative Example 1.

FIG. 7 is a diagram showing the measured results of fracture toughness values of p-type thermoelectric elements of Example 1 and Comparative Example 1.

### EXPLANATION OF NUMERALS

10 . . . Thermoelectric conversion module, 11 . . . p-type thermoelectric element, 12 . . . n-type thermoelectric element, 13 . . . first electrode member, 14 . . . second electrode member, 15, 18 and 21 . . . bonding layer, 16 and 17 . . . substrate, 19 and 20 . . . metal plate, 30 . . . heat exchanger, 40 . . . exhaust heat utilizing power system.

### MODE FOR CARRYING OUT THE INVENTION

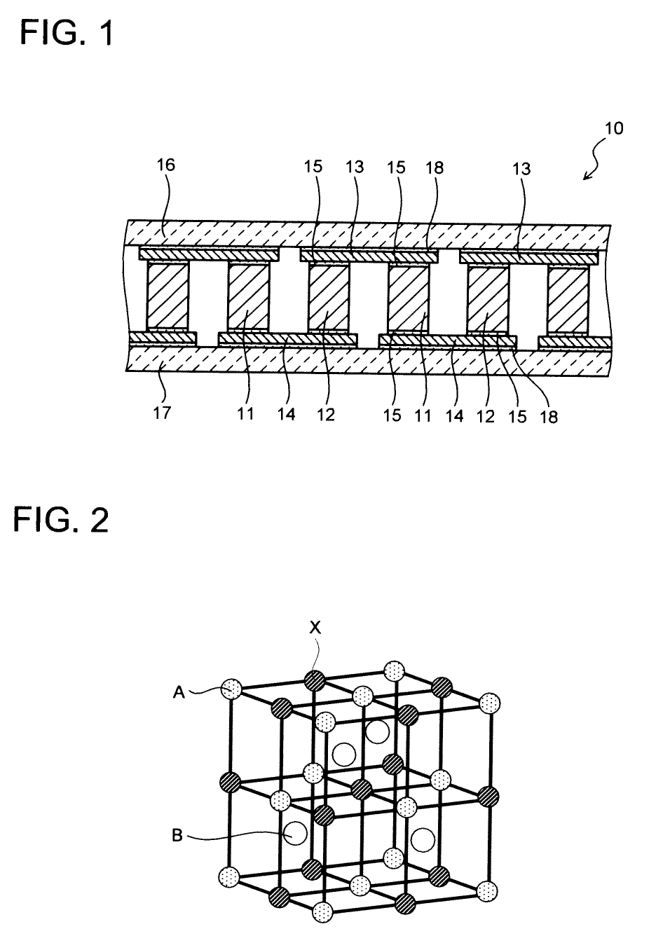

Modes of conducting the present invention will be described below with reference to the drawings. FIG. 1 is a sectional view showing a structure of a thermoelectric conversion module according to an embodiment of the present invention. A thermoelectric conversion module 10 shown in the drawing has plural p-type thermoelectric elements 11 and plural n-type thermoelectric elements 12. The p-type thermoelectric elements 11 and the n-type thermoelectric elements 12 are alternately arranged on the same plane and in a matrix pattern as an entire module to configure a thermoelectric element group.

A first electrode member 13 is arranged on one p-type thermoelectric element 11 and one n-type thermoelectric element 12 adjacent to it to connect them. On the other hand, a second electrode member 14 is arranged below one p-type thermoelectric element 11 and one n-type thermoelectric element 12 adjacent to it to connect them. The first electrode member 13 and the second electrode member 14 are arranged in a state that they are displaced from each other by one element. Thus, the plural p-type thermoelectric elements 11 and the plural n-type thermoelectric elements 12 are electrically connected in series. Specifically, the first and second electrode members 13 and 14 are arranged so that DC current is sequentially flown through the p-type thermoelectric element 11, the n-type thermoelectric element 12, the p-type thermoelectric element 11, the n-type thermoelectric element 12, . . . .

The first and second electrode members 13 and 14 and the p-type and n-type thermoelectric elements 11 and 12 are bonded via a bonding layer 15. The first and second electrode members 13 and 14 are preferably composed of a metal material having as a main component at least one type selected from Cu, Ag and Fe. Since such metal materials are soft, they serve to ease a thermal stress when bonded to the thermoelectric elements 11 and 12. Therefore, it is possible to enhance the reliability, e.g., a heat cycle property, of the bonded portions between the first and second electrode members 13 and 14 and the thermoelectric elements 11 and 12 against a thermal stress. In addition, since the metal material having Cu, Ag or Fe as a main component excels in electrical conductivity, electric power generated by, for example, the thermoelectric conversion module 10 can be taken out efficiently.

A first substrate 16 which is commonly bonded to the plural electrode members 13 is disposed outside (surface opposite to the surface bonded to the thermoelectric elements 11 and 12) of the first electrode member 13. A second substrate 17 which is commonly bonded to the plural electrode members 14 is also disposed outside of the second electrode member 14. The first and second electrode members 13 and 14 are respectively supported by the first and second substrates 16 and 17 to maintain the module structure.

The first and second substrates 16 and 17 are preferably composed of a ceramic substrate having as a main component at least one type selected from aluminum nitride, silicon nitride, silicon carbide, alumina and magnesia excelling in thermal conductance. Since the silicon carbide has conductive property, its surface is provided with an insulating layer when it is used as the first and second substrates 16 and 17. The silicon nitride substrate as described in JP-A 2002-203993 (KOKAI) is preferable as a ceramic substrate. Since the silicon nitride substrate has excellent properties such as a coefficient of thermal conductivity of 65 W/m·K or more and a three-point bending strength of 600 MPa or more, a defect due to insufficient strength or the like does not occur even when a large number of thermoelectric elements 11 and 12 are mounted on it.

The p-type thermoelectric elements 11 and the n-type thermoelectric elements 12 are composed of a thermoelectric material (half-Heusler material) which has as a main phase an intermetallic compound having an MgAgAs type crystal structure. The main phase indicates a phase having the highest volume fraction among the configured phases. The half-Heusler material is being watched with interest as a novel thermoelectric conversion material, and its high thermoelectric performance has been reported. The half-Heusler compound is an intermetallic compound which is represented by a chemical formula ABX and has a cubic MgAgAs type crystal structure. The half-Heusler compound has a crystal structure that atoms B are inserted into an NaCl type crystal lattice based on atoms A and atoms X as shown in FIG. 2.

The half-Heusler compound is a general term for a compound having an MgAgAs type crystal structure, and individual elements composing the ABX are known to include many types. As an A-site element, there is used at least one element selected from III group elements (Sc, rare-earth element, etc.), IV group elements (Ti, Zr, Hf, etc.) and V group elements (V, Nb, Ta, etc.). As a B-site element, there is used at least one element selected from VII group elements (Mn, Tc, Re, etc.), VIII group elements (Fe, Ru, Os, etc.), IX group elements (Co, Rh, Ir, etc.) and X group elements (Ni, Pd, Pt, etc.). As an X-site element, there is used at least one element selected from XIII group elements (B, Al, Ga, In and Tl), XIV group elements (C, Si, Ge, Sn, Pb, etc.), and XV group elements (N, P, As, Sb and Bi).

A specific example of the half-Heusler compound is a compound which has a composition represented by a general formula:

AₓB_{y}X_{100-x-y} (1)

(where, A represents at least one type of element selected from Ti, Zr, Hf and rare-earth element, B represents at least one type of element selected from Ni, Co and Fe, X represents at least one type of element selected from Sn and Sb, and x and y represent a numeral satisfying 30≦x≦35 atom % and 30≦y≦35 atom %).

The half-Heusler compound applied to the thermoelectric elements 11 and 12 is further desired to apply a compound which has a composition represented by a general formula:

(TiₐZr_{b}Hf_{c})ₓB_{y}X_{100-x-y} (2)

(where, B represents at least one type of element selected from Ni, Co and Fe, X represents at least one type of element selected from Sn and Sb, and a, b, c, x and y represent a numeral satisfying 0≦a≦1, 0≦b≦1, 0≦c≦1, a+b+c=1, 30≦x≦35 atom % and 30≦y≦35 atom %).

The half-Heusler compounds represented by the formulae (1) and (2) exhibit a particularly high Seebeck effect and have a usable high temperature (specifically, 300° C. or higher). Therefore, they are effective for the thermoelectric elements 11 and 12 of the thermoelectric conversion module 10 which is used for a power generator and the like using a high temperature heat source. In the formula (1) and the formula (2), an amount (x) of the A-site element is preferably in a range of 30-35 atom % to obtain a high Seebeck effect. Similarly, an amount (y) of the B-site element is preferably in a range of 30-35 atom %.

As the rare-earth element configuring the A-site element, it is desirable to use Y, La, Ce, Pr, Nd, Sm, Gd, Tb, Dy, Ho, Er, Tm, Yb, Lu or the like. In the formula (1) and the formula (2), the A-site element may be partially substituted by V, Nb, Ta, Cr, Mo, W or the like. The B-site element may be partially substituted by Mn, Cu or the like. The X-site element may be partially substituted by Si, Mg, As, Bi, Ge, Pb, Ga, In or the like.

The p-type and n-type thermoelectric elements 11 and 12 composed of the half-Heusler material described above have a fracture toughness value K_{1C} of not less than 1.3 MPa·m^{1/2} and less than 10 MPa·m^{1/2}. Since the half-Heusler material which is a component material for the thermoelectric elements 11 and 12 has the intermetallic compound as the main phase, it has been considered that it is poor in a fracture toughness value. But, according to this embodiment, the fracture toughness value K_{1C} of not less than 1.3 MPa·m^{1/2} is realized by improving a method of producing the half-Heusler material, and the like. Thus, it becomes possible to suppress crack generation in the thermoelectric elements 11 and 12 due to a thermal stress generated in the bonded portions between the thermoelectric elements 11 and 12 and the electrode members 13 and 14 and also an increase of internal resistance and breakage of the module due to the crack generated in the thermoelectric elements 11 and 12. It is preferable that the fracture toughness value K_{1C} of the thermoelectric elements 11 and 12 is not less than 1.5 MPa·m^{1/2}.

It is preferable that a variation in the fracture toughness value K_{1C} is not more than ±15% for the p-type thermoelectric elements 11 and the n-type thermoelectric elements 12, and it is more preferable that the variation in a combination of the p-type thermoelectric elements 11 and the n-type thermoelectric elements 12 is not more than ±15%. The thermoelectric conversion module 10 has a structure that the p-type thermoelectric elements 11 and the n-type thermoelectric elements 12 are alternately connected in series as shown in FIG. 1. When the variation in the fracture toughness value of each of the p-type thermoelectric elements 11 and the n-type thermoelectric elements 12 is so large as to exceed ±15%, breakage tends to occur in the element having a relatively small fracture toughness value, resulting in a possibility that the entire module fails to function. Occurrence of breakage in particular thermoelectric elements 11 and 12 can be suppressed, and the reliability of the entire module can be improved as a result by determining the variation in the fracture toughness value K_{1C} of each of the p-type thermoelectric elements 11 and the n-type thermoelectric elements 12 to be not more than ±15% and also the variation in the fracture toughness value K_{1C} of the combination of the p-type thermoelectric elements 11 and the n-type thermoelectric elements 12 to be small to not more than ±15%.

The variation in the fracture toughness value K_{1C} of the p-type thermoelectric elements 11 (variation in the fracture toughness value K_{1C} of the n-type thermoelectric elements 12 is substantially same) is calculated according to the following equation (1) based on an average value of the fracture toughness values K_{1C} of any ten p-type thermoelectric elements 11 selected from the plural p-type thermoelectric elements 11 and a furthest value which is a fracture toughness value K_{1C} farthest from the average value among the fracture toughness values K_{1C} of the ten p-type thermoelectric elements 11.

Variation(%)=((average value−furthest value)/average value)×100 (1)

And, the variation (variation in the fracture toughness value K_{1C} of thermoelectric element) in the fracture toughness value K_{1C} of the combination of the p-type thermoelectric elements 11 and the n-type thermoelectric elements 12 is calculated according to the above equation (1) based on an average value of the fracture toughness values K_{1C} of a total of twenty of the above-described ten p-type thermoelectric elements 11 and ten n-type thermoelectric elements 12 and the furthest value.

For example, the thermoelectric elements 11 and 12 composed of a half-Heusler material having a fracture toughness value K_{1C} of not less than 1.3 MPa·m^{1/2} is produced as follows. First, an alloy having a desired half-Heusler composition is produced by a melting method or the like. It is pulverized to produce alloy powder having a particle diameter distribution peak in two ranges of 20-30 μm and 80-90 μm. The obtained alloy powder is sintered at a temperature of 1050° C. or higher while pressurizing to not less than 30 MPa to obtain a half-Heusler material (sintered body) having a fracture toughness value K_{1C} of not less than 1.3 MPa·m^{1/2}.

Since the variation in the fracture toughness value K_{1C} of the produced half-Heusler material (sintered body) is small, the p-type thermoelectric elements 11 or the n-type thermoelectric elements 12 having a variation of not more than ±15% in the fracture toughness value K_{1C} can be obtained, and the variation in the fracture toughness value K_{1C} of a combination of the p-type thermoelectric elements 11 and the n-type thermoelectric elements 12 can also be determined to be not more than ±15%. The alloy powder may be produced by an atomization process or the like. Since the atomization process can control the particle diameter relatively easily, it is effective as a process of producing a raw material powder for the half-Heusler material. When the alloy powder produced by the atomization process or the alloy powder undergone a heat treatment is used, the half-Heusler material is made to have a homogenized texture, and it becomes possible to reduce the variation in the fracture toughness value K_{1C} of the p-type thermoelectric elements 11, the n-type thermoelectric elements 12, and the combination of them.

When alloy powder having a particle diameter distribution peak in two ranges of 20-30 μm and 80-90 μm is used for the raw material powder for the half-Heusler material, the density of the sintered body is improved, and voids having a diameter of not less than 3 μm can be prevented from being produced. Since powder having a small particle diameter is filled into the gaps in powder having a large particle diameter, the amount of voids produced when the powder is sintered can be decreased. The size and amount of voids have a large influence on the fracture toughness value and the like. Therefore, it becomes possible to improve the fracture toughness value K_{1C} of the half-Heusler material to not less than 1.3 MPa·m^{1/2}.

When the alloy powder has only one particle diameter distribution peak, a high fracture toughness value cannot be obtained, and when each particle diameter peak is excessively large or small, the fracture toughness value lowers. In addition, when the temperature for sintering the alloy powder is lower than 1050° C. or when the pressurizing force is lower than 30 MPa, the fracture toughness value lowers.

By fabricating the above-described half-Heusler material (sintered body) into a desired element shape, the thermoelectric elements 11 and 12 having a fracture toughness value K_{1C} of not less than 1.3 MPa·m^{1/2} can be realized. It is difficult to enhance the fracture toughness value K_{1C} of the half-Heusler material to not less than 10 MPa·m^{1/2}, and an occurrence rate of the thermoelectric conversion modules 10 having decreased reliability is increased. By using the thermoelectric elements 11 and 12 composed of a half-Heusler material having a fracture toughness value K_{1C} of not less than 1.3 MPa·m^{1/2} and less than 10 MPa·m^{1/2}, it becomes possible to realize the thermoelectric conversion module 10 which is repeatedly durable against a superimposed stress due to a residual stress generated when the module is produced (bonded) and against a thermal stress generated during use at a high temperature (e.g., 300° C. or higher).

By using the above-described half-Heusler material (sintered body), the p-type thermoelectric elements 11 or the n-type thermoelectric elements 12 having the variation of not more than ±15% in the fracture toughness value K_{1C} can be obtained, and the variation in the fracture toughness value K_{1C} of the combination of the p-type thermoelectric elements 11 and the n-type thermoelectric elements 12 can be made not more than ±15%. To provide the p-type thermoelectric elements 11, the n-type thermoelectric elements 12, and the combination of the p-type thermoelectric elements 11 and the n-type thermoelectric elements 12 with the variation of not more than ±15% in the fracture toughness value K_{1C}, it is preferable to use a half-Heusler material (sintered body) which is determined to have the same raw material composition, production conditions and the like.

It is preferable that the half-Heusler material which is a component material for the p-type and n-type thermoelectric elements 11 and 12 has a three-point bending strength of not less than 120 MPa and less than 350 MPa, a Vickers hardness of not less than 500 Hv and less than 1050 Hv and a Young's modulus of not less than 140 GPa and less than 320 GPa. It becomes possible to improve more the heat cycle property of the thermoelectric conversion module 10 by satisfying the above mechanical properties. If the individual properties become lower than the lower limit values, a crack is easily caused by a stress, and if the individual properties exceed the upper limit values, reliability tends to become low. The half-Heusler material having the above mechanical properties can be obtained by applying the above described production method.

It is determined that a particle diameter of the raw material powder (alloy powder) indicates a value measured by the laser diffraction method according to JIS-Z8825. A fracture toughness value indicates a value measured according to the IF method of JIS-R1607. A test piece has its surface polished to Ra=0.1 μm or below before measurement, and an indent load of an indenter is determined to be 2 Kgf (19.6N). A three-point bending strength is determined to indicate a value measured according to JIS-R1601. Vickers hardness is determined to indicate a value measured according to JIS-R1610. Young's modulus is determined to indicate a value measured according to JIS-R1602.

It is preferable to use a metal brazing material for the bonding layer 15 between the p-type and n-type thermoelectric elements 11 and 12 and the electrode members 13 and 14. For example, the active metal brazing material is a brazing material having at least one type of active metal selected from Ti, Zr and Hf, and not only a mechanically strong bonded structure can be obtained, but also a bonded structure having small electrical contact resistance and thermal resistance can be realized. As the active metal brazing material, it is preferable to use a brazing material which has as a main component at least one selected from Ag, Cu and Ni and contains at least one type of active metal selected from Ti, Zr and Hf in a range of 0.1-10 mass %.

The active metal brazing material is preferably an Ag—Cu-active metal brazing material containing at least one type of active metal selected from Ti, Zr and Hf in a range of 0.1-8 mass %, Ag in a range of 60-75 mass %, and a balance of Cu. Ag and Cu are preferably in a ratio to form a eutectic composition. The Ag—Cu-active metal brazing material may contain at least one selected from Sn and In in a range of 8-18 mass % if necessary and may contain carbon in a range of 0.5-3 mass %. The active metal brazing material shows good wettability to the thermoelectric elements 11 and 12 composed of the half-Heusler material and forms a firmly bonded layer structure. Thus, it becomes possible to realize bonding with the electrode members 13 and 14 by mechanically firm bonding and bonding with small electrical and thermal loss at the bonded interface.

Bonding of the thermoelectric elements 11 and 12 and the electrode members 13 and 14 by the active metal brazing material is performed by heating to a temperature in a range of, for example, 760 to 930° C. By bonding the thermoelectric elements 11 and 12 and the electrode members 13 and 14 at such a high temperature, the bonding strength between the thermoelectric elements 11 and 12 and the electrode members 13 and 14 can be maintained even when the thermoelectric conversion module 10 is used under an environmental temperature of, for example, 300° C. or higher and 600° C. or below. Therefore, the thermoelectric conversion module 10 suitably used under the environmental temperature of 300° C. or higher can be provided. The active metal brazing material can also be applied to bonding between the electrode members 13 and 14 and the substrates 16 and 17.

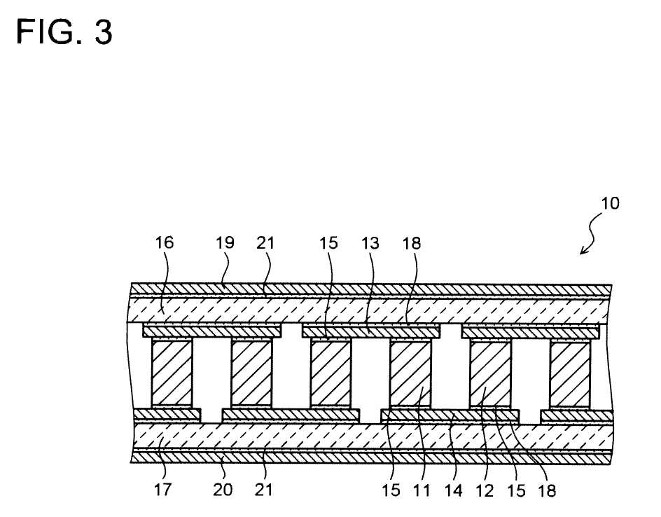

The thermoelectric conversion module 10 is composed of the above-described elements, but metal plates 19 and 20 made of the same material as that of the electrode members 13 and 14 may be disposed more outside of the first and second substrates 16 and 17 as shown in, for example, FIG. 3. The metal plates 19 and 20 are bonded to the substrates 16 and 17 via a bonding layer 21 applying the active metal brazing material in the same manner as the bonding between the electrode members 13 and 14 and the substrates 16 and 17. Occurrence or the like of a crack due to a thermal expansion difference between the substrates 16 and 17 and the electrode members 13 and 14 can be suppressed by bonding the metal plates (electrode members 13 and 14 and the metal plates 19 and 20) made of the same material to both sides of the substrates 16 and 17.

For example, the thermoelectric conversion module 10 shown in FIG. 1 or FIG. 3 is used by disposed the first substrate 16 on the low temperature side (L) and the second substrate 17 on the high temperature side (H) to provide a temperature difference between the upper and lower substrates 16 and 17. For example, the second substrate 17 is disposed under a high temperature environment of 300° C. or higher. An electric potential difference is generated between the first electrode member 13 and the second electrode member 14 based on the temperature difference between the substrates 16 and 17, and electric power can be taken out by connecting a load to the electrode terminal. The thermoelectric conversion module 10 is used effectively as the power generating module.

The thermoelectric elements 11 and 12 composed of the half-Heusler material are usable at a high temperature (e.g., 300° C. or higher) and have high thermoelectric conversion performance and a fracture toughness value K_{1C} of not less than 1.3 MPa·m^{1/2} and less than 10 MPa·m^{1/2}. In addition, the internal resistance and thermal resistance of the entire thermoelectric conversion module 10 are also reduced. Thus, it becomes possible to realize a power generator utilizing a high-temperature heat source and excelling in high efficiency and reliability. According to this embodiment, it is possible to realize the thermoelectric conversion module 10 that the module output to the mounted areas of the thermoelectric elements 11 and 12 is not less than 1.3 W/cm².

The thermoelectric conversion module 10 is not limited to the use of power generation to convert heat into electric power but also can be used for the heating or cooling usage to convert electric power to heat. In other words, when DC current is flown to the p-type thermoelectric element 11 and the n-type thermoelectric element 12 which are connected in series, heat is radiated at one substrate, and heat is absorbed at the other substrate. Therefore, a subject to be treated can be heated by disposing the subject on the substrate on the heat radiation side. Otherwise, the subject can be cooled by disposing it on the heat-absorbing substrate to remove heat from it. For example, a semiconductor manufacturing apparatus controls a semiconductor wafer temperature, and the thermoelectric conversion module 10 can be applied to the temperature control. The thermoelectric temperature control device is provided with the thermoelectric conversion module 10 and uses its cooling or heating function to control the temperature.

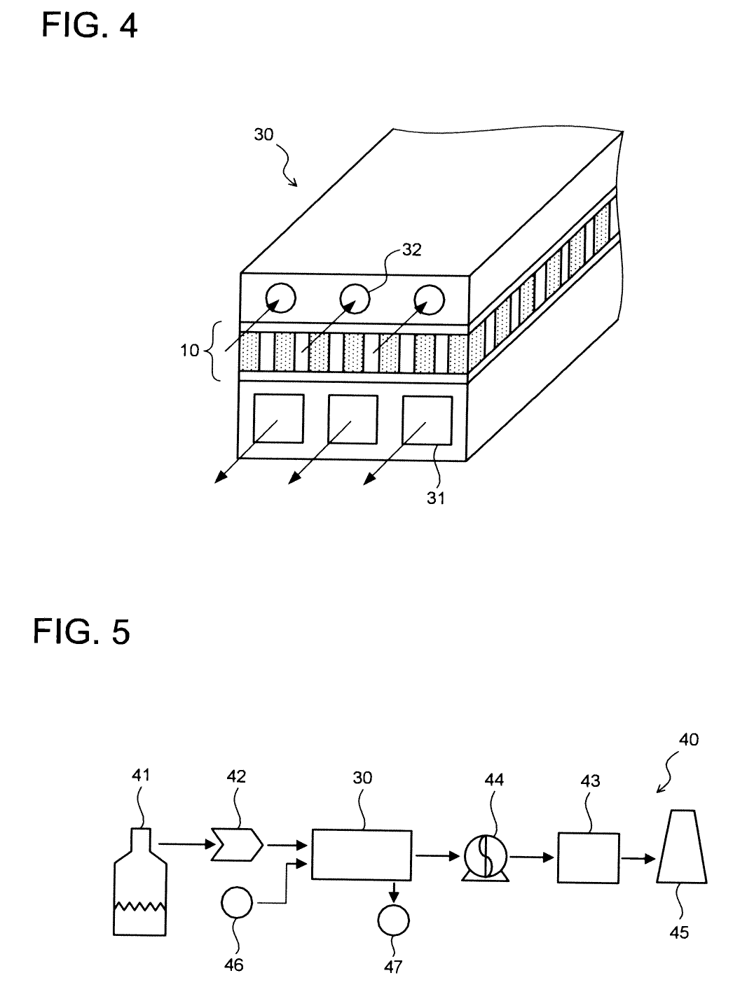

An embodiment of the heat exchanger of the present invention is described below. The heat exchanger according to this embodiment is provided with the thermoelectric conversion module 10 according to the above-described embodiment. The heat exchanger basically has a heating surface and a cooling surface and has a structure that the thermoelectric conversion module 10 is incorporated between them. FIG. 4 is a perspective view showing a structure of the heat exchanger according to the embodiment of the invention. The heat exchanger 30 shown in FIG. 4 has gas passages 31 disposed in contact with one side surface of the thermoelectric conversion module 10 and water passages 32 disposed in the opposite side surface.

For example, a high temperature exhaust gas from a waste incineration furnace is introduced into the gas passages 31. Cooling water is introduced into the water passages 32. One side face of the thermoelectric conversion module 10 is made to form a high-temperature side by the high temperature exhaust gas flowing through the gas passages 31, and the other is made to form a low-temperature side by the cooling water flowing through the water passages 32. Thus, a temperature difference is produced between both ends of the thermoelectric conversion module 10 to take out electric power. To the heating surface, it is possible to apply not only the high temperature exhaust gas from the combustion furnace, but also, for example, the exhaust gas of an automobile engine, the water pipe within the boiler or the like, and a combustion portion itself for combusting various types of fuels can also be applied.

An embodiment of the thermoelectric generator of the invention is described below. The thermoelectric generator of this embodiment is provided with the heat exchanger 30 of the above-described embodiment. The thermoelectric generator basically has a heat supply unit for supplying the heat exchanger 30 with heat for power generation and generates electric power by converting the heat supplied from the heat supply unit into electric power by the thermoelectric conversion module 10 in the heat exchanger 30.

FIG. 5 shows a structure of an exhaust heat-utilizing power system applying the exhaust heat of a waste incineration furnace as an example of the thermoelectric generator applying the heat exchanger 30 according to the embodiment of the invention. The exhaust heat-utilizing power system 40 shown in FIG. 5 has a structure that the heat exchanger 30 according to the embodiment is added to a waste incineration system comprising an incinerator 41 for burning combustible waste, an air blowing fan 44 for blowing air to exhaust smoke treatment equipment 43 by absorbing an exhaust gas 42 and a chimney 45 for diffusing the exhaust gas 42 into the atmosphere. When the waste is burnt by the incinerator 41, the high temperature exhaust gas 42 is produced. The exhaust gas 42 is introduced into the heat exchanger 30 and cooling water 46 is also introduced at the same time, a temperature difference is generated between both ends of the thermoelectric conversion module 10 in the heat exchanger 30, and electric power is taken out. The cooling water 46 is discharged as hot water 47.

The thermoelectric power generation system applying the heat exchanger of the invention is not limited to the waste incineration equipment but can also be applied to facilities having various types of incinerators, heating furnaces, melting furnaces and the like. It is also possible to use an exhaust pipe of an automobile engine as the gas passage for the high temperature exhaust gas and the water pipe within the boiler of a steam thermal power generating plant as a heat supply means. For example, the heat exchanger of the invention is disposed on the water pipe or the fin surface of the water pipe within the boiler of the steam thermal power generating plant such that the high temperature side is on the side of the boiler interior and the low temperature side is on the side of the water pipe. Thus, electric power and steam supplied to the steam turbine can be obtained at the same time, and the efficiency of the steam thermal power generating plant can be improved. In addition, a means for supplying heat to the heat exchanger may be a combustion portion itself, such as the combustion portion of a combustion heating device, for burning various types of fuels.

### EXAMPLES

Specific examples and evaluated results according to the present invention are described below.

### Example 1

The thermoelectric conversion module whose structure is shown in FIG. 3 was produced by the following procedure. First, a production example of the thermoelectric element is described.

(N-Type Thermoelectric Element)

Ti, Zr and Hf each having a purity of 99.9%, Ni and Sn each having a purity of 99.99% and Sb having a purity of 99.999% were prepared as raw materials. They were weighed and mixed so as to have a composition (Ti_{0.3}Zr_{0.35}Hf_{0.35})NiSn_{0.994}Sb_{0.006}. The material mixture was charged into a copper hearth which was water cooled in an arc furnace, and the furnace interior was evacuated to 2×10⁻³ Pa. Then, Ar having a high purity of 99.999% was introduced to have −0.04 MPa, and the material mixture was arc-melted in the decompressed Ar atmosphere.

The obtained metal lump was pulverized to produce alloy powder having a particle diameter distribution peak in two ranges of 20-30 μm and 80-90 μm. The alloy powder was filled into a 100-mm carbon mold and undergone pressure sintering in the Ar atmosphere of 30 MPa under conditions of 1200° C. and three hours to obtain a disk-like sintered body having a diameter of 100 mm. The sintered body was measured for a fracture toughness value by the IF method according to JIS-R1607. As a result, it was found that the fracture toughness value was 1.8 MPa·m^{1/2}. And, the sintered body had a three-point bending strength of 198 MPa, a Vickers hardness of 665Hv, and a Young's modulus of 160 GPa. Thus, when the alloy powder having two or more peaks in a particle diameter distribution is sintered, a target half-Heusler material having a fracture toughness value, a three-point bending strength, a Vickers hardness, a Young's modulus, etc. can be obtained.

Then, rectangular parallelepiped elements having a side length of 2.7 mm and a height of 3.3 mm were cut out from the obtained sintered body to obtain n-type thermoelectric elements. Any ten of the cutout n-type thermoelectric elements were measured for a fracture toughness value. As a result, it was found that the fracture toughness value had an average value of 1.8 MPa·m^{1/2}, a minimum value of 1.7 MPa·m^{1/2} and a maximum value of 2.0 MPa·m^{1/2}, and the variation determined from the above equation (1) was +11%. And, the n-type thermoelectric elements had a resistivity of 1.20×10⁻² Ωmm, a Seebeck coefficient of −280 μV/K and a thermal conductivity of 3.3 W/m·K at 700K.

(P-Type Thermoelectric Element)

Ti, Zr, Hf and Co each having a purity of 99.9%, Sb having a purity of 99.999%, and Sn having a purity of 99.99% were prepared as raw materials. They were weighed and mixed so as to obtain a composition (Ti_{0.3}Zr_{0.35}Hf_{0.35})CoSb_{0.85}Sn_{0.15}. The material mixture was charged into a copper hearth which was water cooled in an arc furnace, and the furnace interior was evacuated to a vacuum degree of 2×10⁻³ Pa. Then, Ar having a high purity of 99.999% was introduced to have −0.04 MPa to provide a decompressed Ar atmosphere, and arc melting was performed.

The obtained metal lump was pulverized to prepare alloy powder having a particle diameter distribution peak in two ranges of 20-30 μm and 80-90 μm. The alloy powder was filled into a 100-mm carbon mold and subjected to pressure sintering in the Ar atmosphere of 30 MPa under conditions of 1350° C. and three hours to obtain a disk-like sintered body having a diameter of 100 mm. The sintered body was measured for a fracture toughness value by the IF method. As a result, the fracture toughness value was 1.7 MPa·m^{1/2}. The sintered body had a three-point bending strength of 172 MPa, a Vickers hardness of 591 Hv and a Young's modulus of 128 GPa.

A rectangular parallelepiped element having a side length of 2.7 mm and a height of 3.3 mm was cut out from the obtained sintered body to obtain p-type thermoelectric elements. Any ten of the cutout p-type thermoelectric elements were measured for a fracture toughness value. As a result, it was found that the fracture toughness value had an average value of 1.7 MPa·m^{1/2}, a minimum value of 1.6 MPa·m^{1/2} and a maximum value of 1.9 MPa·m^{1/2}, and the variation determined from the above equation (1) was +12%. The p-type thermoelectric elements have a resistivity of 2.90×10⁻² Ωmm, a Seebeck coefficient of 309 μV/K and a thermal conductivity of 2.7 W/m·K at 700K.

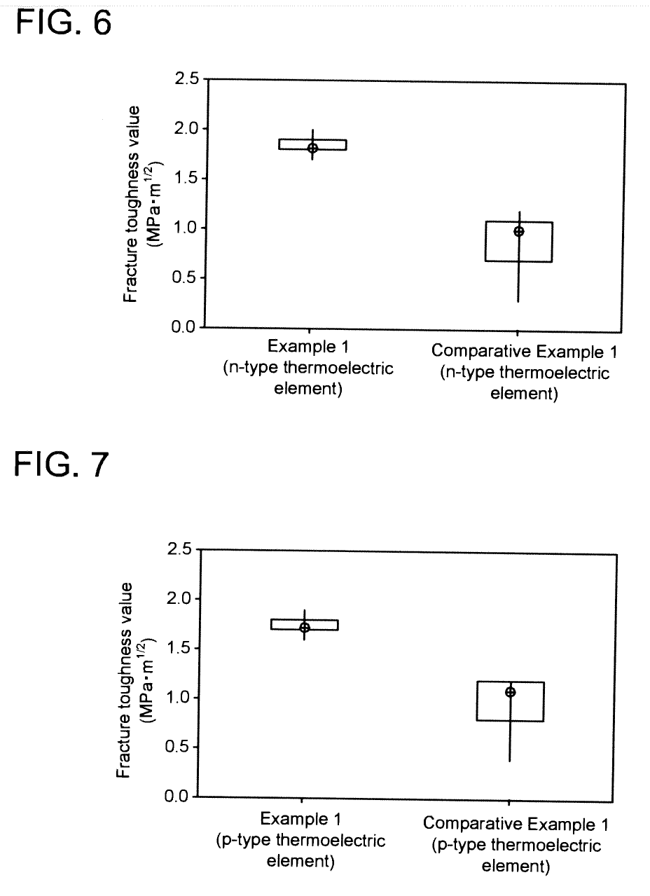

Table 1 collectively shows an average value, a minimum value and a maximum value of the fracture toughness values of the above-described individual n-type thermoelectric elements and p-type thermoelectric elements and the variation determined by the above equation (1). And, FIGS. 6 and 7 show various characteristics of the fracture toughness values of the above-described n-type thermoelectric elements and p-type thermoelectric elements. In FIGS. 6 and 7, the circle mark indicates the average value, the vertical line indicates a range between the minimum value and the maximum value, and the frame-like portion indicates a range that two or more n-type thermoelectric elements or p-type thermoelectric elements were measured for the fracture toughness values.

Table 2 shows an average value, a minimum value, a maximum value of the fracture toughness values of a total of twenty thermoelectric elements of the above-described ten n-type thermoelectric elements and ten p-type thermoelectric elements and the variation determined by the above-described equation (1). As shown in Table 2, it was found that an average value of the fracture toughness values of the thermoelectric elements totaled from the n-type thermoelectric elements and the p-type thermoelectric elements was 1.75 MPa·m^{1/2}, a minimum value was 1.6 MPa·m^{1/2}, a maximum value was 2.0 MPa·m^{1/2}, and the variation determined by the above equation (1) was +14%.

Then, the above-described n-type thermoelectric elements and p-type thermoelectric elements were used to produce a thermoelectric conversion module as follows.

(Thermoelectric Conversion Module)

In this embodiment, a thermoelectric conversion module was produced by using a Si₃N₄ ceramics plate (a thermal conductivity: 80 W/m·K, and a three-point bending strength: 800 MPa) as first and second substrates, and a Cu plate as first and second electrode members. A bonding material having an active metal brazing material of Ag:Cu:Sn:Ti:C=61:24:10:4:1 in mass ratio formed into a paste form was screen printed on the Si₃N₄ ceramics plate having a side of 40 mm and thickness of 0.7 mm.

After the active metal brazing material paste was dried, a Cu electrode plate which was 2.8 mm long, 6.1 mm wide and 0.25 mm thick was disposed lengthwise in six and breadthwise in 12 on it. A total of 72 Cu electrode plates were disposed on the Si₃N₄ ceramics plate. Bonding between the Si₃N₄ ceramics plate and the Cu electrode plates was performed by a heat treatment in vacuum of 0.01 Pa or less at 800 degrees C. for 20 minutes. The above-described bonding material was used to bond the Cu plates on the entire surface of the other side of the Si₃N₄ ceramics plate on which the Cu electrode plates were disposed.

The above bonding material was additionally screen printed on the Cu electrode plates and dried to obtain a thermoelectric module substrate. Two thermoelectric module substrates were used and superposed with a thermoelectric element sandwiched between them. The thermoelectric element had p-type and n-type thermoelectric elements alternately disposed on the bonding material printed on the Cu electrode plate and arranged in a square shape with six sets vertically and 12 columns horizontally to have a total of 72 sets. To arrange the thermoelectric elements, rod-shape silicon nitride plates having a thickness of 0.45 mm were disposed in a grid pattern which was used as a fixing jig. The individual thermoelectric elements and the Cu electrode plate were bonded by performing a heat treatment of the laminated body in vacuum of 0.01 Pa or less at 800° C. for 20 minutes.

The produced thermoelectric conversion module was measured for a thermoelectric power generation characteristic under the matched load conditions that a load having the same resistance value as that of the internal resistance of the module was connected with the high-temperature side set to 500° C., and the low-temperature side set to 55° C. The resistance of the module was measured from the I-V characteristics of the thermoelectric conversion module to determine the resistance value in the bonded interface. As a result, it was found that the internal resistance value was 1.6752, and the maximum output was 21.8 W. A TCT test was performed by setting the high temperature side of the thermoelectric conversion module to 500° C. and the low temperature side to 25° C., holding for ten minutes and returning to room temperature. Even after the operation was repeated for 1000 times or more, no break or shape change was observed in the thermoelectric element. In addition, after the TCT test, the thermoelectric power generation characteristic was measured again to confirm that the initial performance was maintained.

### Example 2

In Example 2, the alloy powder used as the raw material to be sintered for the thermoelectric element was produced by the atomization process. The atomization process is relatively easy to control a particle diameter, and alloy powder having a distribution peak in two ranges of 20-30 μm and 80-90 μm was produced in the same manner as in Example 1. The n-type and p-type thermoelectric elements were produced in the same manner as in Example 1 except that the above alloy powder was used, and a thermoelectric conversion module was also produced similarly. The TCT test was performed on the obtained thermoelectric conversion module under the same conditions as in Example 1. As a result, it was confirmed that even after the operation was repeated for 1000 times or more, no break or shape change was observed in the thermoelectric element, and the initial performance was maintained.

### Examples 3 and 4

The hot press of the thermoelectric element preparation conditions (sintering conditions) of Example 1 was changed to HIP, and a thermoelectric element having mechanical properties different from those of Example 1 was produced. Thermoelectric conversion modules were produced in the same manner as in Example 1 except that the above thermoelectric element was used. The thermoelectric conversion modules were undergone the TCT test. Table 3 shows the mechanical properties of the individual thermoelectric elements and the TCT evaluated results of the thermoelectric conversion modules. The TCT evaluated results in Table 3 show the number of times that breakage, peeling and the like did not occur at the thermoelectric element and the bonded portion when it was determined that the high temperature side of each of the individual thermoelectric conversion modules was 500° C. and the low temperature side was 25° C., and an operation of keeping the above condition for 10 minutes and lowering to room temperature was repeated. A indicates that the number of times was 1000 or more, B indicates that the number of times was not less than 100 and less than 1000, C indicates that the number of times was less than 100, and D indicates occurrence of break at the time of module bonding.

### Example 5

N-type and p-type thermoelectric elements were produced in the same manner as in Example 1 except that the heat sintering conditions in Example 1 were changed to those of 1050° C. and thirty hours in a 30-MPa Ar atmosphere. Thermoelectric conversion modules were produced in the same manner as in Example 1 except that the produced thermoelectric elements were used. The thermoelectric conversion modules were undergone the TCT test. Table 3 shows the mechanical properties of the individual thermoelectric elements and the TCT evaluated results of the thermoelectric conversion modules.

### Comparative Example 1

N-type and p-type thermoelectric elements were produced in the same manner as in Example 1 except that alloy powder having an average particle diameter of 55 μm and only one peak in a particle diameter distribution was used. The elements were measured for the fracture toughness value by the IF method in the same manner as in Example 1. It was found that the fracture toughness value of the n-type thermoelectric element had an average value of 1.0 MPa·m^{1/2}, a minimum value of 0.3 MPa·m^{1/2} and a maximum value of 1.2 MPa·m^{1/2}, the variation determined by the above-described formula was −70%, and the fracture toughness value of the p-type thermoelectric element had an average value of 1.1 MPa·m^{1/2}, a minimum value of 0.4 MPa·m^{1/2} and a maximum value of 1.2 MPa·m^{1/2}, and the variation determined by the above-described formula was −64%. Table 1 and FIGS. 6 and 7 show the above results together with those of Example 1.

Table 2 shows an average value, a minimum value, a maximum value and the variation determined by the above-described equation (1) of the fracture toughness values of the thermoelectric elements combining the n-type thermoelectric elements and p-type thermoelectric elements described above together with the results of Example 1. As shown in Table 2, the fracture toughness values of the thermoelectric elements combining the n-type thermoelectric elements and the p-type thermoelectric elements had an average value of 1.05 MPa·m^{1/2}, a minimum value of 0.3 MPa·m^{1/2} and a maximum value of 1.2 MPa·m^{1/2}, and the variation determined by the above-described formula was −71%. The thermoelectric conversion module produced from those thermoelectric elements failed to function as a module because separation was caused from the thermoelectric element near the bonded portion when an operation that it was kept at 500° C. for 10 minutes and the temperature was lowered to room temperature was repeated twice.

### Comparative Example 2

N-type and p-type thermoelectric elements were produced in the same manner as in Example 1 except that alloy powder having a particle diameter distribution peak in two ranges of 5-15 μm and 25-35 μm was used. The individual elements (sintered bodies) were measured for a fracture toughness value by the IF method. As a result, it was found that the fracture toughness values of the n-type thermoelectric elements had an average value of 1.1 MPa·m^{1/2} and the fracture toughness values of the p-type thermoelectric elements had an average value of 1.1 MPa·m^{1/2}. The thermoelectric conversion module produced from those thermoelectric elements failed to function as a module because breakage was caused near the bonded portions in the high temperature bonding process when the module was produced.

TABLE 1

| | | Fracture toughness value | | | |
|---|---|---|---|---|---|
| | | Average | Minimum | Maximum | |
| | | value | value | value | Variation |
| | | [MPa · m^{1/2}] | [MPa · m^{1/2}] | [MPa · m^{1/2}] | [%] |
| N-type | Example 1 | 1.8 | 1.7 | 2.0 | +11 |
| thermoelectric | Comparative | 1.0 | 0.3 | 1.2 | −70 |
| element | Example 1 | | | | |
| P-type | Example 1 | 1.7 | 1.6 | 1.9 | +12 |
| thermoelectric | Comparative | 1.1 | 0.4 | 1.2 | −64 |
| element | Example 1 | | | | |

TABLE 2

| | Fracture toughness value | | | |
|---|---|---|---|---|
| | Average | Minimum | Maximum | Vari- |
| | value | value | value | ation |
| | [MPa · m^{1/2}] | [MPa · m^{1/2}] | [MPa · m^{1/2}] | [%] |
| Example 1 (N-type | 1.75 | 1.6 | 2.0 | +14 |
| and p-type thermo- | | | | |
| electric elements) | | | | |
| Comparative | 1.05 | 0.3 | 1.2 | −71 |
| Example 1 (N-type | | | | |
| and p-type thermo- | | | | |
| electric elements) | | | | |

TABLE 3

| | | Thermoelectric element characteristics | | | | Module |
|---|---|---|---|---|---|---|
| | | Fracture | Three-point | Vickers | Young's | characteristics |
| | | toughness value | bending strength | hardness | modulus | TCT evaluated |
| | | (MPa · m^{1/2}) | (MPa) | (Hv) | (GPa) | results |
| Example 1 | N-type | 1.8 | 198 | 665 | 160 | A |
| | P-type | 1.7 | 172 | 591 | 128 | |
| Example 2 | N-type | 1.9 | 230 | 840 | 271 | A |
| | P-type | 1.8 | 206 | 755 | 203 | |
| Example 3 | N-type | 1.5 | 116 | 570 | 133 | A |
| | P-type | 1.5 | 107 | 503 | 128 | |
| Example 4 | N-type | 1.7 | 108 | 487 | 171 | A |
| | P-type | 1.7 | 116 | 455 | 166 | |
| Example 5 | N-type | 1.3 | 199 | 472 | 169 | B |
| | P-type | 1.3 | 260 | 443 | 180 | |
| Comparative | N-type | 1.0 | 118 | 402 | 128 | C |
| Example 1 | P-type | 1.1 | 110 | 368 | 119 | |
| Comparative | N-type | 1.1 | 354 | 1006 | 330 | D |
| Example 2 | P-type | 1.1 | 372 | 1060 | 326 | |

It is apparent from Table 3 that the thermoelectric conversion modules of Examples 1 to 5 using a thermoelectric element having a fracture toughness value K_{1C} of not less than 1.3 MPa·m^{1/2} and less than 10 MPa·m^{1/2} are repeatedly durable against the residual stress generated when module bonding is performed and a thermal stress generated when they are used at a high temperature. Therefore, it is seen that they are excellent in a heat cycle property. In other words, it becomes possible to provide the thermoelectric conversion module excelling in utility and reliability.

As shown in Tables 1 and 2 and FIGS. 6 and 7, it is seen that the thermoelectric conversion module of Example 1 that the variation in the fracture toughness value K_{1C} of each of the n-type thermoelectric elements and the p-type thermoelectric elements is not more than ±15%, and it is also seen that the thermoelectric conversion module of Example 1 that the variation in the fracture toughness value K_{1C} of the thermoelectric element combining the n-type thermoelectric element and the p-type thermoelectric element is not more than ±15% is excellent in a heat cycle property in comparison with the thermoelectric conversion module of the Comparative Example 1 that the variation is other than above.

### Example 6

The heat exchanger shown in FIG. 4 was produced by the following procedure. First, the thermoelectric conversion modules of Example 1 were arranged between a heat resistant steel flat plate and a corrosion resistant steel flat plate and fixed by them to produce a stacked plate. Output terminals from the individual modules were connected in series. Thus, the heat exchanger with the thermoelectric conversion modules was obtained with the heat resistant steel side of the stacked plate determined as a heating portion and the corrosion resistant steel side determined as a cooling portion. High temperature exhaust gas and cooling water were flown to the heat exchanger with the thermoelectric conversion module. For example, the waste incineration system shown in FIG. 5 is provided with the heat exchanger with the thermoelectric conversion module, thereby enabling to provide a boiler that steam and hot water can be obtained, and power generation can be performed as well.

The above-described heat exchanger with the thermoelectric conversion module is disposed on the water pipe or the fin surface of the water pipe within the boiler of the steam thermal power generating plant, the heat resistant steel flat plate side is determined on the side of the boiler interior, and the corrosion resistant steel flat plate side is determined on the side of the water pipe. Thus, electric power and steam supplied to the steam turbine can be obtained at the same time, and the steam thermal power generating plant with the efficiency improved can be obtained. In other words, when it is assumed that the power generation efficiency of the steam thermal power generating plant to generate electric power by the steam turbine only is ηA and the thermoelectric conversion efficiency of the heat exchanger is ηT, they are expressed as ηA=ηT+(1−ηT)ηP. And, when a heat exchanger having the thermoelectric conversion efficiency ηT is mounted on the steam thermal power generating plant having power generation efficiency ηP, the power generation efficiency can be improved by (1−ηTP) ηT only.

In addition, a thermoelectric power generating system was configured by fitting the heat exchanger with the thermoelectric conversion module to a midpoint of an exhaust pipe (exhaust gas passage) of an automobile engine. This thermoelectric power generating system takes out DC power from heat energy of the exhaust gas by the thermoelectric conversion module and regenerates in a storage battery mounted on the automobile. Thus, the drive energy of the AC generator (alternator) provided in the automobile is reduced, and the fuel consumption rate of the automobile can be improved.

The heat exchanger may be air cooled. By applying an air-cooled heat exchanger to a combustion heating apparatus, the combustion heating apparatus that external supply of electric energy is not required can be realized. In a combustion heating apparatus comprising a combustion portion which burns a fuel such as a petroleum liquid fuel, a gas fuel or the like, a housing portion which houses the combustion portion and has an opening for emitting air including heat generated by the combustion portion to the front of the apparatus, and an air blowing portion which sends the air including the heat generated by the combustion portion to the front of the apparatus, the air-cooled heat exchanger is mounted on an upper part of the combustion portion. By this combustion heating apparatus, DC power can be obtained from a part of the heat of the combustion gas by the thermoelectric conversion module to drive the air blowing fan at the air blowing portion.

### INDUSTRIAL APPLICABILITY

The thermoelectric conversion module of the invention has a thermoelectric element which is composed of a thermoelectric material having as a main phase an intermetallic compound having an MgAgAs type crystal structure, and has a fracture toughness value K_{1C} of not less than 1.3 MPa·m^{1/2} and less than 10 MPa·m^{1/2}. Thus, reliability can be secured for a long period even in a high temperature environment, and it is effectively used for a heat exchanger, a thermoelectric temperature control device, a thermoelectric generator and the like.

What is claimed is:

1. A thermoelectric conversion module, comprising a first electrode member arranged on a low temperature side, a second electrode member arranged on a high temperature side in opposite to the first electrode member, and thermoelectric elements arranged between and connected electrically with both the first and second electrode members,
wherein the thermoelectric elements are composed of a thermoelectric material containing an intermetallic compound having an MgAgAs type crystal structure as a main phase and have a fracture toughness value K_{1C} of not less than 1.3 MPa·m^{1/2} and less than 10 MPa·m^{1/2}.

2. The thermoelectric conversion module according to claim 1,
wherein a p-type thermoelectric element and an n-type thermoelectric element composing the thermoelectric element each have a variation of not more than ±15% in the fracture toughness value K_{1C}.

3. The thermoelectric conversion module according to claim 1,
wherein the thermoelectric element has a variation of not more than ±15% in the fracture toughness value K_{1C}.

4. The thermoelectric conversion module according to claim 1,
wherein the thermoelectric element has a three-point bending strength of not less than 120 MPa and less than 350 MPa.

5. The thermoelectric conversion module according to claim 1,
wherein the thermoelectric element has a Vickers hardness of not less than 500 Hv and less than 1050 Hv.

6. The thermoelectric conversion module according to claim 1,
wherein the thermoelectric element has a Young's modulus of not less than 140 GPa and less than 320 GPa.

7. The thermoelectric conversion module according to claim 1,
wherein the thermoelectric element has a fracture toughness value K_{1C} of not less than 1.5 MPa·m^{1/2} and less than 10 MPa·m^{1/2}.

8. The thermoelectric conversion module according to claim 1,
wherein the second electrode member is arranged in a high temperature environment of not less than 300° C.

9. The thermoelectric conversion module according to claim 1,
wherein the thermoelectric element has a composition which is represented by a general formula:
A_{X}B_{y}X_{100-X-y}
(where, A represents at least one type of element selected from Ti, Zr, Hf and rare-earth elements, B represents at least one type of element selected from Ni, Co and Fe, X represents at least one type of element selected from Sn and Sb, and x and y represent a numeral satisfying 30≦x≦35 atom % and 30≦y≦35 atom %).

10. The thermoelectric conversion module according to claim 1,
wherein the thermoelectric element is bonded to the first and second electrode members via an active metal brazing material layer.

11. The thermoelectric conversion module according to claim 1,
wherein the first and second electrode members are made of a metal material having as a main component at least one type selected from Cu, Ag and Fe.

12. The thermoelectric conversion module according to claim 1,
wherein a ceramic substrate having as a main component at least one type selected from silicon nitride, aluminum nitride, silicon carbide, alumina and magnesia is arranged on a surface opposite to the surface bonded to the thermoelectric element of the first and second electrode members.

13. The thermoelectric conversion module according to claim 1,
wherein the thermoelectric elements include plural p-type thermoelectric elements and plural n-type thermoelectric elements, and the plural p-type thermoelectric elements and the plural n-type thermoelectric elements are arranged alternately and connected in series by the first and second electrode members.

14. A heat exchanger, comprising:
a heating surface, a cooling surface, and the thermoelectric conversion module according to claim 1 disposed between the heating surface and the cooling surface.

15. A thermoelectric temperature control device, comprising the thermoelectric conversion module according to claim 1,
wherein a cooling or heating function of the thermoelectric conversion module is used to adjust a temperature.

16. A thermoelectric generator comprising the heat exchanger according to claim 14 and a heat supply unit for supplying heat to the heat exchanger,
wherein electric power is generated by converting the heat supplied by the heat supply unit into the electric power by the thermoelectric conversion module in the heat exchanger.

17. The thermoelectric generator according to claim 16,
wherein the heat supply unit has an exhaust gas line of a combustion furnace, a boiler interior water pipe, an exhaust pipe of an automobile engine or a combustion portion of a combustion heating device.
